(19) United States
(12) Patent Application Publication
(10) Pub. No.: US 2017/0367227 A1
(43) Pub. Date: Dec. 21, 2017

(54) COMPONENT PLACEMENT MACHINE AND ATTACHMENT

(71) Applicant: Panasonic Intellectual Property Management Co., Ltd., Osaka (JP)

(72) Inventors: HIROKI KOBAYASHI, Fukuoka (JP); MASAFUMI HIZUKURI, Saga (JP); NOBORU FURUTA, Fukuoka (JP); TAKASHI MAEDA, Fukuoka (JP)

(21) Appl. No.: 15/610,660

(22) Filed: Jun. 1, 2017

(30) Foreign Application Priority Data
Jun. 15, 2016 (JP) 2016-118898

(51) Int. Cl. H05K 13/04

(52) U.S. Cl. CPC H05K 13/0408; H05K 13/0417

(57) ABSTRACT

A component placement machine which picks up a component supplied by a tape feeder and installs the component on a board, includes a block part that includes a fitting hole to which a protrusion extending to a rear side from the tape feeder is fitted and a connection member that is provided in the block part, and connects the protrusion to the block part by elastically pressing a side surface of the protrusion fitted to the fitting hole.

### BACKGROUND

### 1. Technical Field

The present disclosure relates to a component placement machine which picks up a component supplied by a tape feeder and installs the component on a board using an installing head.

### 2. Description of the Related Art

A component placement machine picks up a component supplied by a component supply device and installs the component on a board using an installing head. As a type of the component supply device included in such a component placement machine, a tape feeder which supplies the component to a component supply opening by pitch feeding a carrier tape using a sprocket is known. The tape feeder is mounted in a feeder base included in the component placement machine, but if excitation force which is generated at the time of moving the installing head is applied, the tape feeder is greatly vibrated in a width direction (horizontal direction) where rigidity is weak, and suction error of the component due to the installing head is caused to be generated.

For this reason, in the related art, a damping mechanism which suppresses vibration of the tape feeder mounted in the feeder base is devised.

For example, PTL 1 to be described later discloses an example of which a configuration in which a protrusion for positioning of the tape feeder side is fitted to a fitting hole provided in the feeder base side at the time of mounting the tape feeder in the feeder base is used. In the damping mechanism, a ball member which is provided so as to protrude to the outside of an outer peripheral surface of the protrusion is energized by a spring, and the ball member presses an inner wall surface of the fitting hole in a state in which the protrusion is fitted to the fitting hole.

### CITATION LIST

### Patent Literature

PTL 1: Japanese Patent Unexamined Publication No. 2010-92962.

### SUMMARY

However, in a configuration of the related art described above, the ball member presses the inner wall surface of the fitting hole at a contact point with respect to the inner wall surface, and thus it is necessary that a spring constant of the spring energizing the ball member is increased or the number of the ball members are increased in order to sufficiently exert a damping function. Accordingly, there is a problem in that the damping mechanism is increased in size and costs thereof are increased.

Therefore, the disclosure is to provide a component placement machine which is capable of achieving damping of a tape feeder with an inexpensive configuration and reducing generation of suction errors of the component from the tape feeder due to an installing head.

A component placement machine of the disclosure which picks up a component supplied by a tape feeder and mounts the component on a board includes a block part that includes a fitting hole to which a protrusion extending to a rear side from the tape feeder is fitted and a connection member that is provided in the block part, and connects the protrusion to the block part by elastically pressing a side surface of the protrusion fitted to the fitting hole.

According to this disclosure, damping of the tape feeder is achieved with an inexpensive configuration, and generation of the suction errors of the component from the tape feeder due to the installing head can be reduced.

### BRIEF DESCRIPTION OF THE DRAWINGS

FIG. 1 is a side view of a main part of a component placement machine according to an embodiment of the disclosure;

FIG. 2 is a perspective view illustrating a tape feeder included in the component placement machine with a feeder base and an attachment according to the embodiment of the disclosure;

FIG. 3 is a perspective view illustrating the tape feeder included in the component placement machine with the attachment according to the embodiment of the disclosure;

FIG. 4 is an exploded perspective view of a part of the attachment included in the component placement machine according to the embodiment of the disclosure;

FIG. 5 is a perspective view of a part of the attachment included in the component placement machine according to the embodiment of the disclosure;

FIG. 6 is a sectional plan view of a part of the attachment included in the component placement machine according to the embodiment of the disclosure;

FIG. 7A is a partial sectional side view of the tape feeder and the attachment of the component placement machine according to the embodiment of the disclosure;

FIG. 7B is a partial sectional side view of the tape feeder and the attachment of the component placement machine according to the embodiment of the disclosure;

FIG. 8A is a partial sectional plan view of the tape feeder and the attachment of the component placement machine according to the embodiment of the disclosure;

FIG. 8B is a partial sectional plan view of the tape feeder and the attachment of the component placement machine according to the embodiment of the disclosure;

FIG. 9 is a partial sectional plan view of the tape feeder and the attachment of the component placement machine according to the embodiment of the disclosure;

FIG. 10 is a partial sectional plan view of an attachment of a first modification example of the component placement machine according to the embodiment of the disclosure;

FIG. 11A is a partial sectional plan view of an attachment of a second modification example of the component placement machine according to the embodiment of the disclosure;

FIG. 11B is a partial sectional plan view of the attachment of the second modification example of the component placement machine according to the embodiment of the disclosure;

FIG. 12A is a partial sectional plan view of an attachment of a third modification example of the component placement machine according to the embodiment of the disclosure; and

FIG. 12B is a partial sectional plan view of the attachment of the third modification example of the component placement machine according to the embodiment of the disclosure.

### DETAILED DESCRIPTION

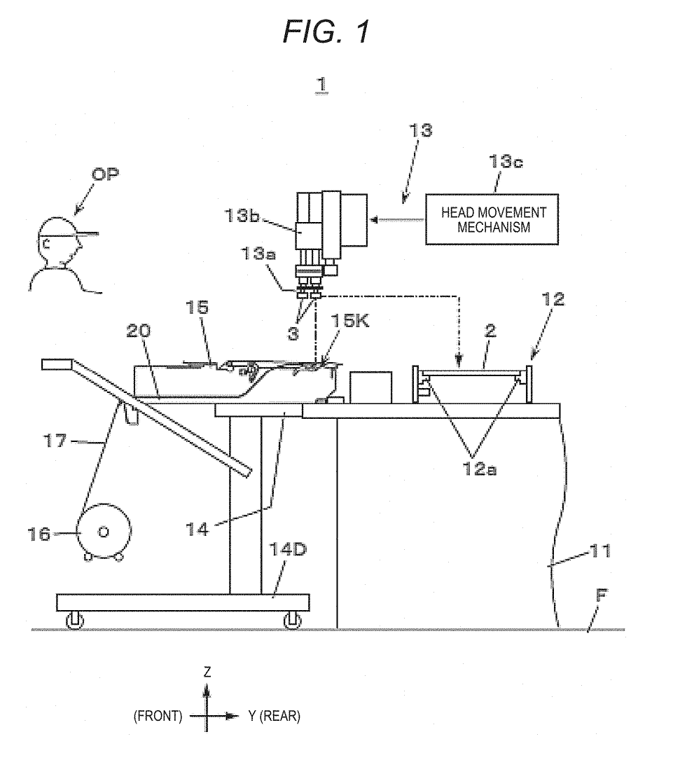

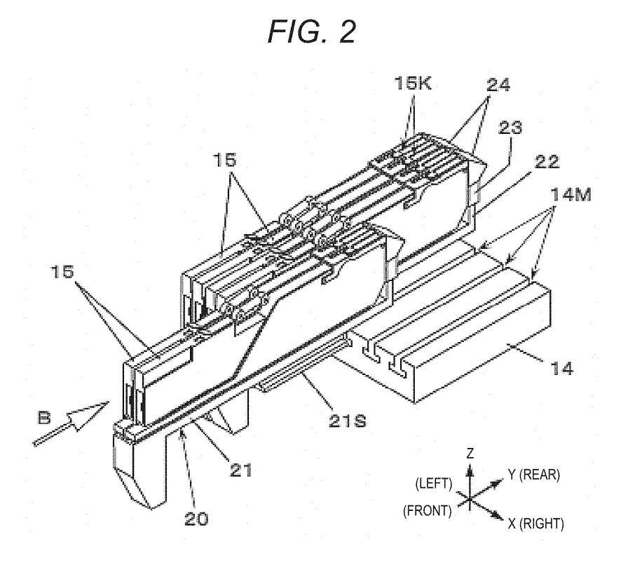

Hereinafter, embodiments of the disclosure will be described with reference to drawings. Component placement machine 1 illustrated in FIG. 1 is a device which installs component 3 on board 2, and is provided with board transporter 12 and component installer 13 on base 11. Feeder base 14 is coupled with base 11. A plurality of tape feeders 15 are mounted on feeder base 14. Here, for convenience of description, a right and left direction of component placement machine 1 when seen from operator OP is set to an X axis direction (refer to FIG. 2), and a front and rear direction thereof is set to a Y axis direction. An up and down direction thereof is set to a Z axis direction.

In FIG. 1, board transporter 12 is provided with a pair of conveyors 12a extending to the X axis direction on base 11. Board transporter 12 supports both end portions of the Y axis direction of board 2 using the pair of conveyors 12a, and transports board 2 in the X axis direction. Component installer 13 is configured with installing head 13b which is provided with suction nozzle 13a and head movement mechanism 13c which moves installing head 13b in a horizontal plan direction. Each suction nozzle 13a is capable of sucking component 3 in a lower end thereof.

In FIG. 1, feeder base 14 is mounted on carriage 14D. Carriage 14D is moved on floor F by operation of operator OP and is coupled with base 11. The plurality of tape feeders 15 are respectively detachably mounted on feeder base 14 in parallel in the X axis direction. In each tape feeder 15, carrier tape 17 pulled out from reel 16 held by carriage 14D is introduced. Component 3 is stored in carrier tape 17. Each tape feeder 15 pitch-feeds carrier tape 17 using a sprocket which is not illustrated, and thus component 3 accommodated in carrier tape 17 is supplied to component supply opening 15K.

Component placement machine 1, first, carries in board 2 send from an upstream process side using board transporter 12 and positions at a work position. Also, tape feeder 15 supplies component 3 to component supply opening 15K, and head movement mechanism 13c reciprocates installing head 13b between tape feeder 15 and board 2. Installing head 13b picks up component 3, which is positioned at component supply opening 15K by tape feeder 15, by sucking the component using suction nozzle 13a, and picked up component 3 is installed on board 2. If installing head 13b installs all components 3 to be installed on board 2 on board 2, board transporter 12 carries out board 2 to a downstream process side. As described above, component placement machine 1 continuously manufactures an installing board.

Component placement machine 1 according to the embodiment is provided with a damping mechanism which suppresses vibration of tape feeder 15 mounted in feeder base 14, and hereinafter, a configuration thereof will be described.

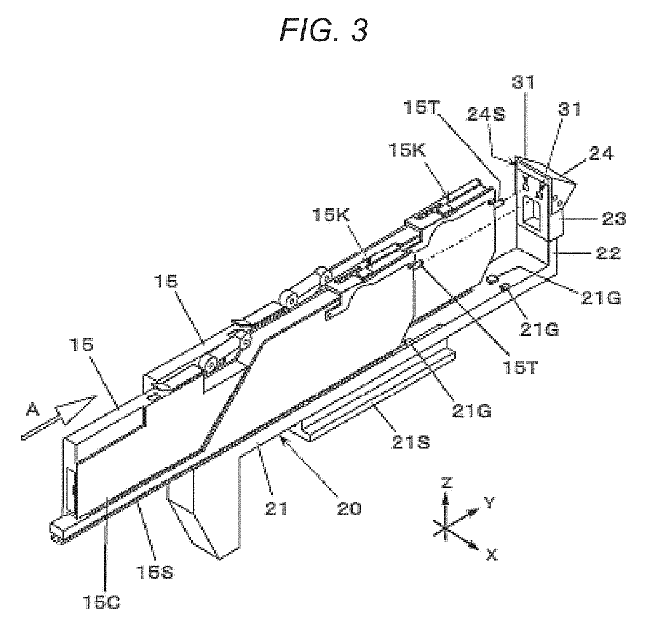

In FIG. 2, tape feeder 15 is mounted in feeder base 14 through attachment 20 which is detachably installed on feeder base 14 (also refer to FIG. 1). In FIG. 2 and FIG. 3, attachment 20 includes horizontal part 21 extending in the Y axis direction, vertical part 22 extending to an upper side from a rear end of the horizontal part, and block part 23 formed on an upper side of vertical part 22. Tape discharging guide 24 is mounted in block part 23.

in FIG. 2 and FIG. 3, two tape feeders 15 can be mounted in attachment 20 in a state in which tape feeders are arranged in parallel with each other. Also, attachment 20 in which two tape feeders 15 (only one tape feeder 15 may be used) are mounted is installed on feeder base 14, and thus tape feeder 15 can be mounted in feeder base 14. The tape discharging guide 24 induces the carrier tape 17 being discharged by tape feeder 15 to a discharging passage, which is not illustrated, formed on base 11, in a tape inducing passage 24S (FIG. 3) formed between tape discharging guide and block part 23.

In FIG. 3, tape feeder 15 includes engaged part 15S which is protruded downwardly on a lower part of case 15C. A plurality of engaged part inserting guides 21G are provided on an upper surface of horizontal part 21 of attachment 20. When tape feeder 15 is mounted in attachment 20, engaged part 15S of tape feeder 15 is guided to the plurality of engaged part inserting guide 21G of attachment 20, and tape feeder 15 is slid from a front side to a rear side of attachment 20 (arrow A illustrated in FIG. 3).

In FIG. 2 and FIG. 3, protruding part 21S which is protruded downwardly is provided on a lower surface of horizontal part 21 of attachment 20. When attachment 20 is mounted in feeder base 14, protruding part 21S of attachment 20 is engaged with tape feeder 14 which is provided in engaging groove 14M (FIG. 2) to extend in the Y axis direction, and is guided from a front side to a rear side of feeder base 14 (arrow B illustrated in FIG. 2).

In FIG. 3, protrusion 15T horizontally protruded and extending to a rear side is provided on an end portion of a rear side of tape feeder 15. Meanwhile, when tape feeder 15 is mounted in attachment 20, fitting hole 31 to which protrusion 15T of tape feeder 15 is fitted from a rear side is provided in block part 23 provided in attachment 20. In the embodiment, two fitting holes 31 are provided to be arranged in the X axis direction. It is because that the two fitting holes are provided by corresponding to two tape feeders 15 mounted in attachment 20.

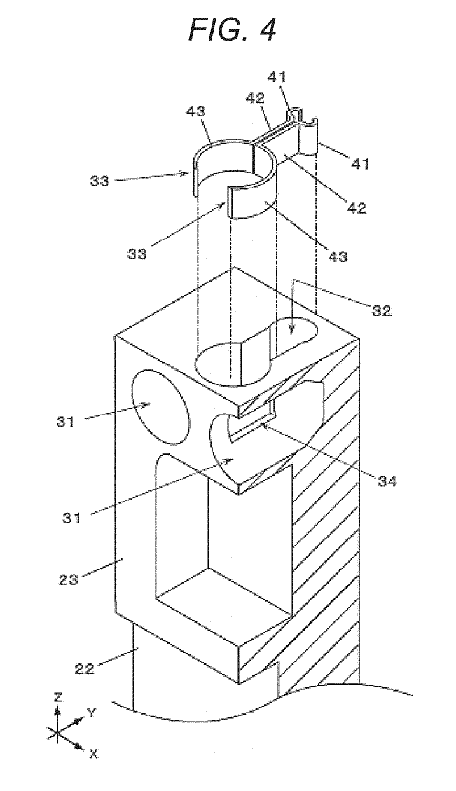

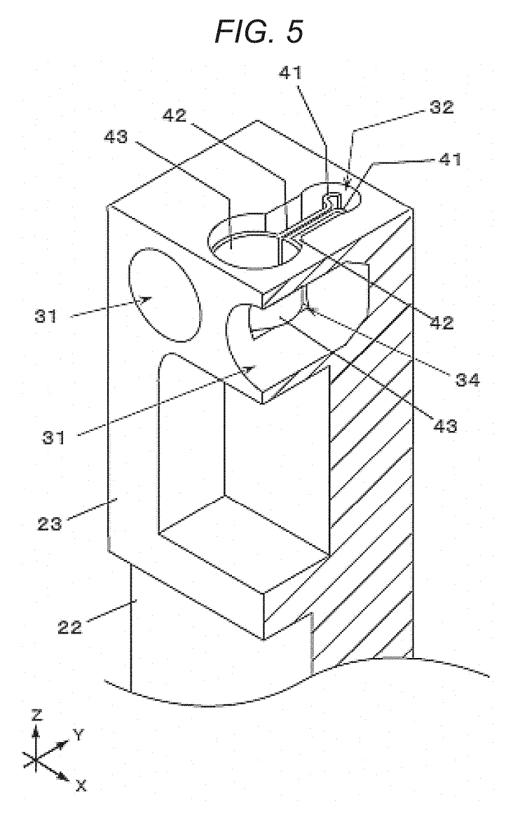

In FIG. 4 and FIG. 5, accommodating space 32 which is opened upwardly is provided in an intermediate part of two fitting holes 31 provided in block part 23. Two plate springs 33 are arranged in accommodating space 32.

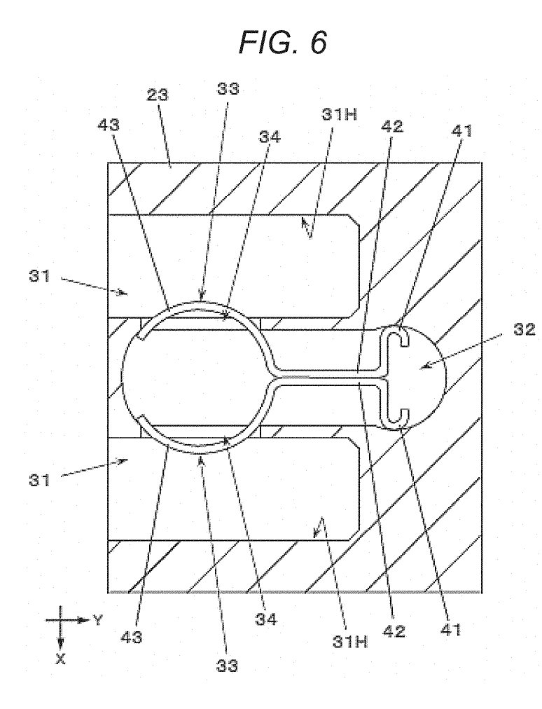

In FIG. 4, FIG. 5, and FIG. 6, each plate spring 33 is provided to extend in the Y axis direction totally (direction where protrusion 15T fitted in fitting hole 31 extends in). Each plate spring 33 includes supporting part 41, intermediate part 42 which is provided to extend forwardly from supporting part 41, and pressing part 43 provided in front of intermediate part 42. Pressing part 43 is a part for elastically pressing a side surface of protrusion 15T fitted to fitting hole 31, and is formed in a shape which is semicircularly curved in a horizontal plane in the embodiment. Two plate springs 33 are disposed in accommodating space 32 in an integrated state, so that intermediate parts 42 are in contacted with each other and two pressing parts 43 are respectively protruded to the outside.

In FIG. 4, each of two fitting holes 31 communicates with accommodating space 32 through passage 34. Two plate springs 33 respectively expose pressing part 43 in fitting hole 31 from passage 34 of a corresponding side (FIG. 5 and FIG. 6).

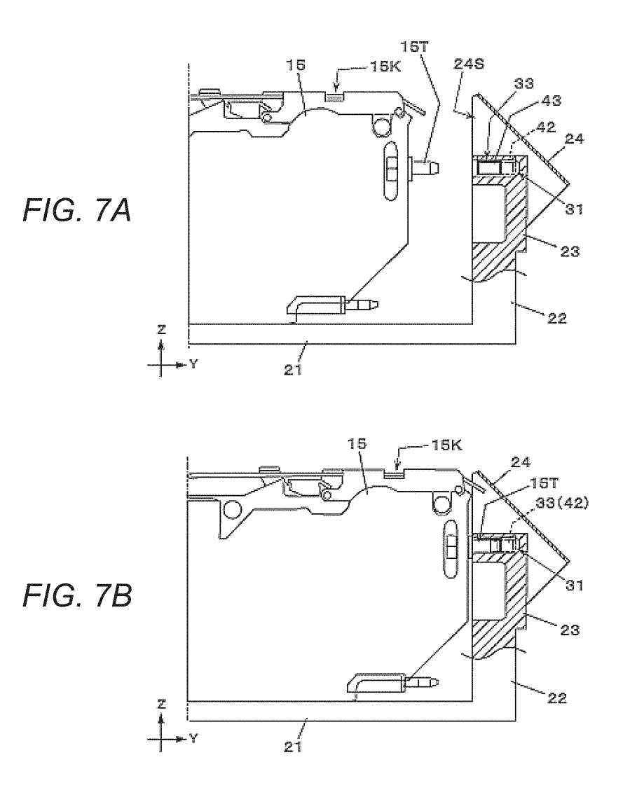

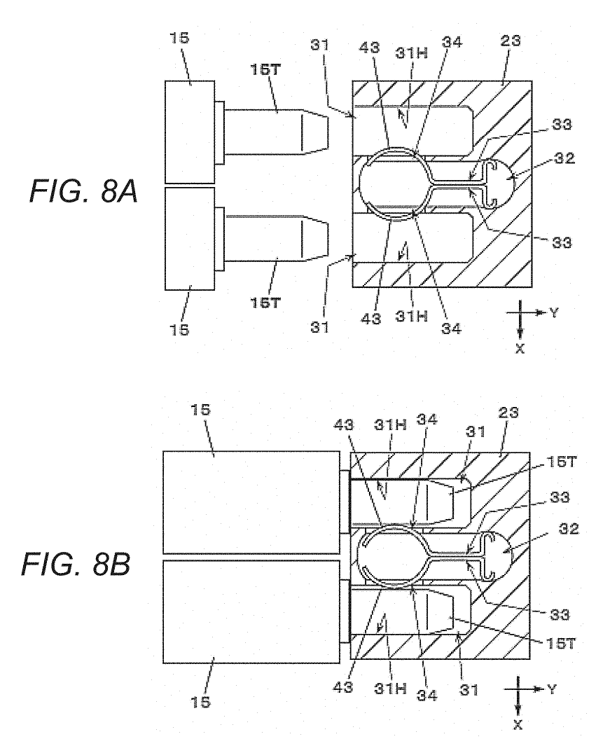

In FIGS. 7A, 7B, and FIGS. 8A and 8B, if tape feeder 15 is mounted in attachment 20, protrusion 15T provided in tape feeder 15 is fitted to fitting hole 31 formed on block part 23 of attachment 20 (FIG. 7A→FIG. 7B and FIG. 8A→FIG. 8B). At this time, pressing part 43 of plate spring 33 being exposed in fitting hole 31 is pushed inside passage 34 (that is, horizontal direction of tape feeder 15), and thus protrusion 15T proceeds rearwardly.

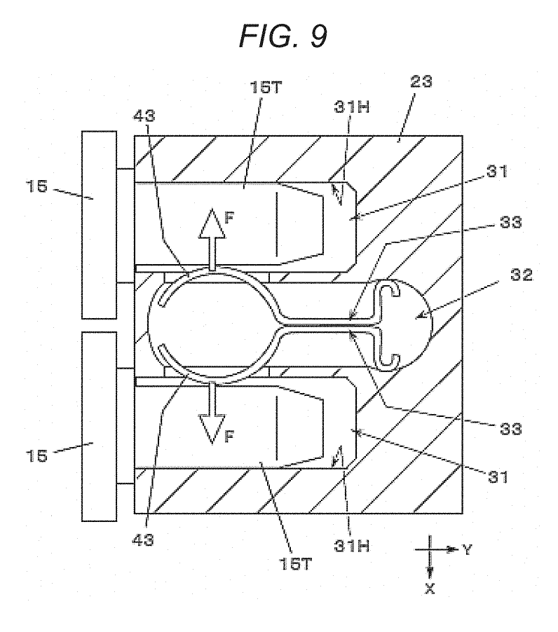

If protrusion 15T fitted to fitting hole 31 makes pressing part 43 of plate spring 33 be pushed, pressing part 43 of plate spring 33 elastically presses a side surface of protrusion 15T in a direction orthogonal to a direction (it is the X axis direction, and a horizontal direction of tape feeder 15) where protrusion 15T extends (arrow F illustrated in FIG. 9). Accordingly, protrusion 15T is pressed to inner wall surface 31H of fitting hole 31 (inner wall surface 31H of side opposite to a side where pressing part 43 is exposed), and is connected to block part 23 (FIG. 8B and FIG. 9).

In the embodiment described above, plate spring 33 provided in block part 23 functions as a connection member which connects protrusion 15T to block part 23 by elastically pressing a side surface of protrusion 15T fitted to fitting hole 31. If protrusion 15T as described above is fitted to fitting hole 31, plate spring 33 connects protrusion 15T to block part 23, and tape feeder 15 is fixed to attachment 20, and is further fixed to feeder base 14. As a result, vibration of tape feeder 15 is suppressed.

Accordingly, compared to PTL 1, since a contacting area of protrusion 15T and pressing part 43 can be increased with a simple configuration, vibration of tape feeder 15 is suppressed.

### First Modification Example

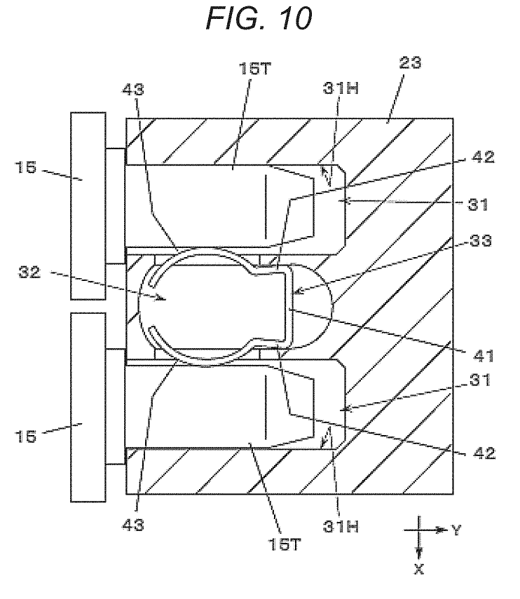

In the above description, two plate springs 33 corresponding to two protrusions 15T are disposed on one accommodating space 32, but as illustrated in a first modification example of FIG. 10, one connection type plate spring 33, which includes two intermediate parts 42 and two pressing parts 43 extending from one supporting part 41, may be disposed inside accommodating space 32. Although such a connection type plate spring 33 is disposed in accommodating space 32, same effect as a case in which two plate spring 33 described above are disposed in accommodating space 32 can be obtained.

That is, as component placement machine 1 according to the embodiment, in a case in which the plurality of tape feeders 15 are mounted in parallel in attachment 20, accommodating space 32 between two fitting holes 31 to which two protrusions 15T including two tape feeders 15 which are adjacently mounted are fitted, is provided on block part 23. One plate spring 33 (connection member) pressing each of two protrusions 15T of two adjacent tape feeders 15 can be disposed in accommodating space 32.

### Second Modification Example

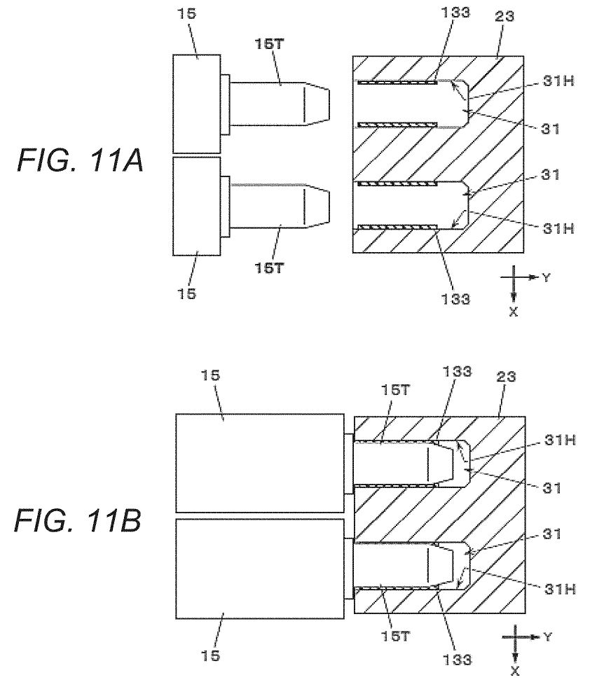

In the embodiment described above, the connection member which connects protrusion 15T fitted to fitting hole 31 to block part 23 is configured with plate spring 33, but the connection member is a member that exerts the same effect, and may be made of an elastic body such as a rubber member. For example, as illustrated in a second modification example of FIGS. 11A and 11B, flat plate shape rubber member 133 is attached to cover the entire inner wall surface 31H of fitting hole 31 and can be used as a connection member. In such a configuration, if protrusion 15T is fitted to fitting hole 31 (FIG. 11A→FIG. 11B), rubber member 133 elastically presses the entire side surface of protrusion 15T. Protrusion 15T is connected to block part 23 in a state of being freely insertably and removably press-fitted to fitting hole 31 (FIG. 11B).

### Third Modification Example

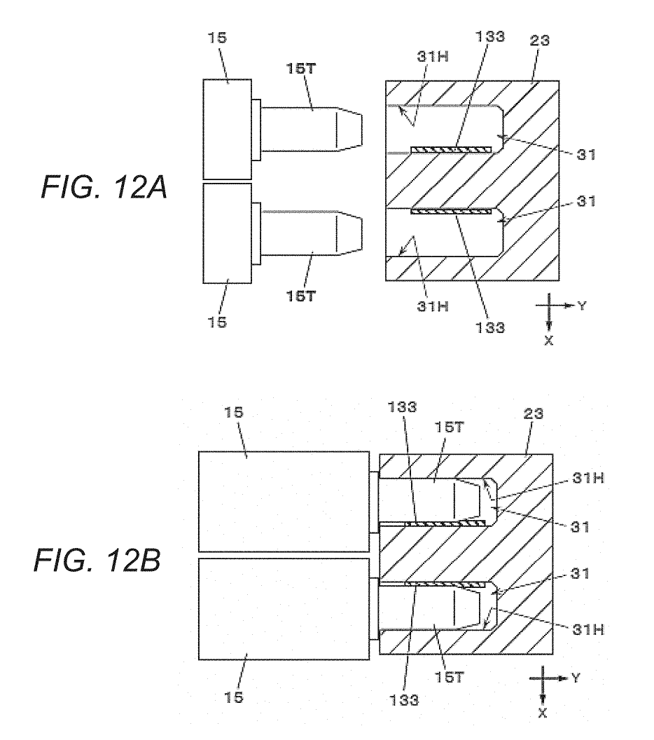

A third modification example is illustrated in FIGS. 12A and 12B. Rubber member 133 extending in a fitting direction (Y axis direction) of protrusion 15T is attached to a part of inner wall surface 31H of fitting hole 31, and can be used as the connection member. In such a configuration, if protrusion 15T is fitted to fitting hole 31 (FIG. 12A→FIG. 12B), rubber member 133 elastically presses a part of the side surface of protrusion 15T. Protrusion 15T is connected to block part 23 in a state of being pressed by inner wall surface 31H of fitting hole 31 (FIG. 12B).

In the embodiment described above, in a case in which rubber member 133 is used as the connection member, the connection member is attached to inner wall surface 31H of fitting hole 31. As a case in which plate spring 33 is used as the connection member, it does not matter that accommodating space 32 is provided in block part 23, rubber member 133 is disposed thereto, and a part thereof is exposed through passage 34.

As described above, in component placement machine 1 of the embodiment, if protrusion 15T extending in a rear side from tape feeder 15 is fitted to fitting hole 31, the connection member (plate spring 33, rubber member 133, and the like) elastically presses the side surface of protrusion 15T, and thus protrusion 15T is connected to block part 23 so that tape feeder 15 is fixed to feeder base 14. As a result, vibration of tape feeder 15 is suppressed. Therefore, according to component placement machine 1, damping of tape feeder 15 can be achieved with an inexpensive configuration. Accordingly, generation of suction error of component 3 from tape feeder 15 using installing head 13b can be reduced.

This disclosure is not limited to the embodiments described above. For example, in the embodiment described above, plate spring 33 is provided to press the side surface of protrusion 15T in horizontal direction of tape feeder 15, but accommodating space 32 may be provided in an upper side or a lower side of each fitting hole 31, and plate spring 33 may press protrusion 15T upwardly or downwardly.

Also, in the embodiment described above, since tape feeder 15 is mounted on feeder base 14 through attachment 20, block part 23 is provided in attachment 20, but in a case in which tape feeder 15 is directly mounted on feeder base 14 not through attachment 20, block part 23 provided with fitting hole 31 and the connection member is provided in feeder base 14.

The component placement machine which is capable of achieving damping of the tape feeder with an inexpensive configuration and reducing generation of the suction error of the component from the tape feeder due to the installing head.

What is claimed is:

1. A component placement machine which picks up a component supplied by a tape feeder and installs the component on a board, comprising:
a block part that includes a fitting hole to which a protrusion extending to a rear side from the tape feeder is fitted; and
a connection member that is provided in the block part, and connects the protrusion to the block part by elastically pressing a side surface of the protrusion fitted to the fitting hole.

2. The component placement machine of claim 1,
wherein the connection member presses the protrusion to an inner wall surface of the fitting hole.

3. The component placement machine of claim 1,
wherein the connection member is configured with a plate spring.

4. The component placement machine of claim 1,
wherein the block part includes an accommodating space which communicates with the fitting hole through a passage, and
wherein the connection member is disposed in the accommodating space, and a pressing part which is a part pressing the protrusion is exposed inside the fitting hole from the passage.

5. The component placement machine of claim 4,
wherein the block part includes two fitting holes to which two protrusions including two tape feeders which are adjacently mounted are fitted,
wherein the accommodating space is provided between the fitting holes, and
wherein one or two connection members pressing each of the two protrusions of the adjacent two tape feeders are disposed in the accommodating space.

6. The component placement machine of claim 1,
wherein the block part is provided with the feeder base or an attachment which is detachably installed on the feeder base.

7. An attachment which is detachably mounted in a feeder base and is provided with a tape feeder, comprising:
a block part that includes a fitting hole to which a protrusion extending to a rear side from the tape feeder is fitted; and
a connection member that is provided in the block part, and connects the protrusion to the block part by elastically pressing a side surface of the protrusion fitted to the fitting hole.
